(19) United States
(12) Patent Application Publication
(10) Pub. No.: US 2009/0102002 A1
(43) Pub. Date: Apr. 23, 2009

(54) PACKAGED SEMICONDUCTOR ASSEMBLIES AND ASSOCIATED SYSTEMS AND METHODS

(75) Inventors: Yong Poo Chia, Singapore (SG); Tongbi Jiang, Boise, ID (US)

Correspondence Address: PERKINS COIE LLP;PATENT-SEA, PO BOX 1247, SEATTLE, WA, 98111-1247, US

(73) Assignee: Micron Technology, Inc., Boise, ID (US)

(21) Appl. No.: 11/969,613

(22) Filed: Jan. 4, 2008

(30) Foreign Application Priority Data
Oct. 23, 2007 (SG) 200717116-8

(51) Int. Cl. H01L 31/00; H01L 21/60

(52) U.S. Cl. 257/433; 438/64; 438/67; 257/E31.113; 257/E21.506

(57) ABSTRACT

Semiconductor packages, packaged semiconductor devices, methods of manufacturing semiconductor packages, methods of packaging semiconductor devices, and associated systems are disclosed. A semiconductor package in accordance with a particular embodiment includes a die having a first side carrying a first bond site electrically connected to a sensor and/or a transmitter configured to receive and/or transmit radiation signals. The semiconductor package also includes encapsulant material at least partially encapsulating a portion of the die. The semiconductor package includes a conductive path from the first bond site to a second bond site, positioned on a back surface of the encapsulant, which can include through-encapsulant interconnects. A cover can be positioned adjacent to the die and be generally transparent to a target wavelength.

### CROSS-REFERENCE TO RELATED APPLICATION

This application claims foreign priority benefits of Singapore Application No. 200717116-8 filed Oct. 23, 2007, which is incorporated herein by reference in its entirety.

### TECHNICAL FIELD

The present disclosure is related to packaged semiconductor devices and associated systems and methods. More specifically, the disclosure provides methods for manufacturing packaged semiconductor devices, methods for packaging semiconductor assemblies, and semiconductor packages formed using such methods.

### BACKGROUND

Packaged semiconductor devices are used in cellular phones, pagers, personal digital assistants, computers and many other types of consumer or industrial electronic products. Semiconductor packages typically include dies mounted to a substrate and encased in a plastic protective covering. The die includes functional features, such as memory cells, processor circuits, imager devices, and interconnecting circuitry. The die also typically includes bond pads to provide an array of external contacts through which supply voltage, electrical signals, and other input/output parameters are transmitted to/from the integrated circuits. Because of their small size and fragility, dies are typically packaged to protect them from the environment and from potentially damaging forces during handling. The die packages provide the microelectronic devices with needed protection and also connect the die bond-pads to a larger array of electrical terminals that are easier to connect to a printed circuit board or other external device.

In one conventional arrangement, dies can be packaged individually using plastic or ceramic packages having a cavity that houses the die. The packages include lead fingers that connect the bond pads on the die to pins on the package. The packages can provide both electrical insulation and mechanical strength for the die, in addition to providing electrical connections to external elements. These semiconductor packages typically increase the volumetric “footprint” of the die (e.g., the height and surface area occupied on a printed circuit board) to a size greater than the die size. However, specific packaging techniques have been used to form packages that are less than 20% greater than the die size.

In other conventional arrangements, dies can be packaged at the wafer level. In these arrangements, a plurality of dies can be processed and packaged simultaneously before being singulated from each other. Manufacturing semiconductor packages at the wafer level includes providing interconnect structures for rerouting electrical signals from die features to external terminals that can be electrically coupled to external elements, such as printed circuit boards. The packaged dies can be tested on the wafer, prior to singulation. The surface area the device occupies on a circuit board or other substrate is typically the size of the die. Because the size of the package and the size of the die are substantially equal, wafer-level packages typically use very small bond-pads assembled in dense arrays having fine pitches between bond-pads to connect the package to external elements.

Packages formed via either of the techniques described above are suitable for installations in digital cameras, camera phones, biometrics and medical instruments, sensors, and/or other such devices. Manufacturers of such electronic products are developing increasingly sophisticated electronic devices while simultaneously reducing their size. To keep pace with demand, incorporated semiconductor components are being manufactured to accommodate the requirements of the electronic products, for example, through dense arrays of input/output terminals, and through processing methods aimed at decreasing the footprint of the device. By decreasing the die size, manufacturers have been able to reduce the size of the overall package; however, with these advances, there has been a significant increase in the costs associated with manufacturing the package.

### BRIEF DESCRIPTION OF THE DRAWINGS

FIG. 1 is a partially schematic, cross-sectional illustration of a packaged semiconductor device in accordance with an embodiment of the disclosure.

FIGS. 2A-2J are partially schematic, cross-sectional illustrations of stages of a method for manufacturing packaged semiconductor assemblies in accordance with an embodiment of the disclosure.

FIG. 3 is a partially schematic, cross-sectional illustration of another packaged semiconductor device in accordance with an embodiment of the disclosure.

FIGS. 4A-4E are partially schematic, cross-sectional illustrations of stages of a method for manufacturing packaged semiconductor assemblies in accordance with an embodiment of the disclosure.

FIG. 5 is a partially schematic, cross-sectional illustration of another packaged semiconductor device in accordance with an embodiment of the disclosure.

FIGS. 6A-6C are partially schematic, cross-sectional illustrations of stages of a method for manufacturing packaged semiconductor assemblies in accordance with an embodiment of the disclosure.

FIG. 7 is a flow chart illustrating a method for packaging a semiconductor die in accordance with an embodiment of the disclosure.

FIG. 8 is a schematic illustration of a system that can include one or more packaged semiconductor devices configured in accordance with several embodiments of the disclosure.

### DETAILED DESCRIPTION

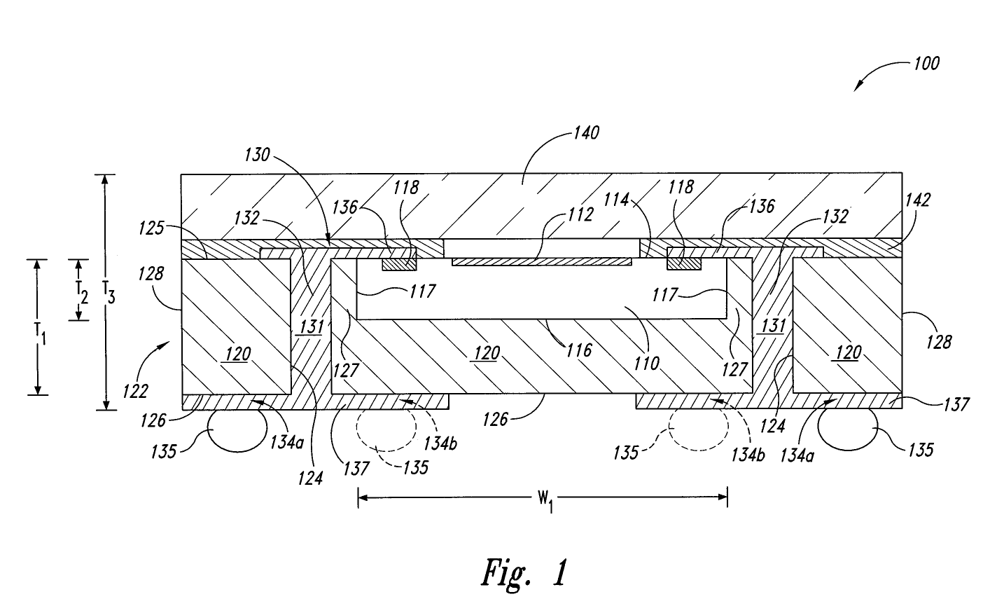

Specific details of several embodiments of the disclosure are described below with reference to packaged semiconductor assemblies, packaged semiconductor devices, methods of manufacturing packaged semiconductor devices, and methods of packaging semiconductor assemblies. Many details of certain embodiments are described below with reference to semiconductor dies. The term “semiconductor die” is used throughout to include a variety of articles of manufacture, including, for example, individual integrated circuit dies, imager dies, sensor dies, and/or dies having other semiconductor features. Many specific details of certain embodiments are set forth in FIGS. 1-8 and the following text to provide a thorough understanding of these embodiments. Moreover, several other embodiments of the disclosure can have configurations, components, and/or procedures different than those described below in this section. A person of ordinary skill in the art, therefore, will accordingly understand that other embodiments of the disclosure may have additional elements, and/or may not have several of the features and elements shown and described below with reference to FIGS. 1-8.

FIG. 1 is a partially schematic, cross-sectional illustration of a semiconductor package 100 configured in accordance with an embodiment of the disclosure. In this embodiment, the semiconductor package 100 can include a die 110 having a sensor and/or transmitter (referred to as a sensor/transmitter 112) that receives and/or transmits radiation. For example, the sensor/transmitter 112 can include an imager device suitable for use in digital cameras, cell phones, and other applications. The semiconductor package 100 can also include an encapsulant 120 (e.g., a mold compound or other encapsulant material) configured to at least partially encapsulate the die 110. The encapsulant material 120 can be molded to form an encapsulant body 122 (e.g., a molded support structure) that is configured to insulate and protect the die 110. The encapsulant body 122 can include a via 124 that extends through the encapsulant material 120 to provide for electrical communication to and/or from the die 110. Accordingly, the package 100 can also include a conductive path 130 that includes conductive material 131 disposed in the via 124, thereby forming a through-encapsulant interconnect 132. In certain embodiments, the through-encapsulant interconnect 132 is offset laterally from the die 110 by an internal portion 127 so that at least a portion of the encapsulant body 122 is between the die 110 and at least a portion of the conductive path 130.

A cover 140 can be secured adjacent to the die 110 and the encapsulant body 122 with an adhesive 142 such as an adhesive film, epoxy, tape, paste, or other suitable material. The cover 140 can be transparent to or at least partially transparent to radiation that is received or transmitted by the sensor/transmitter 112. Accordingly, the cover 140 can protect the components within the package 100, while providing little or no interference with the operation of the sensor/transmitter 112.

In the illustrated embodiment of the package 100, the die 110 can have a first side 114 (e.g., active side) facing a first direction, a second side 116 facing a second direction generally opposite the first direction, and die walls 117 extending between the first side 114 and the second side 116. The sensor/transmitter 112 can be positioned at the first side 114, which can also carry first bond sites 118 for electrically transmitting signals to and from the die 110. The encapsulant body 122, which is in direct contact with the die 110, can include a front surface 125 that is generally flush with the first side 114 of the die 110, a back surface 126 facing a direction generally opposite that of the front surface 125, and exterior side walls 128 extending between the front and back surfaces 125 and 126. In the embodiment illustrated in FIG. 1, the back surface 126 of the encapsulant body 122 is offset from the second side 116 of the die 110. Accordingly a body thickness T₁ between the front surface 125 and the back surface 126 of the encapsulant body 122 is greater than a die thickness T₂ between the first side 114 and the second side 116 of the die 110. For example, the die thickness T₂ can have a value of from about 50 microns to about 850 microns (e.g., 300 microns) and the body thickness T₁ can have a greater value. In other embodiments, the back surface 126 can be generally flush with the second side 116, and the body thickness T₁ can be approximately the same as the die thickness T₂. In such embodiments, the second side 116 can include a dielectric layer (not shown) to electrically insulate the die 110 at the second side 116.

As illustrated in FIG. 1, the via 124 is separated from the die 110 by the internal portion 127 of the encapsulant body 122. Accordingly, the via 124 can extend through the encapsulant body 122 from the front surface 125 to the back surface 126 without contacting the die 110. As a result, the internal portion 127 can electrically insulate the die 110 from the conductive path 130 without the requirement for an additional insulation layer, such as a dielectric layer.

The conductive material 131 disposed in the via 124 can be any of a variety of suitable conductive materials 131 including conductive metals or combinations of conductive metals (e.g., copper, nickel, gold and/or alloys of these metals). In the illustrated embodiment, the conductive material 131 fills the via 124 to form the through-encapsulant interconnect 132. In other embodiments, not shown, the conductive material 131 may not completely fill the via 124. For example, the conductive material 131 can coat an inwardly facing perimeter surface of the via 124 between the front surface 125 and the back surface 126 to form a conductive “barrel”. Additionally, the through-encapsulant interconnect 132 can include a seed layer (not shown) at least partially covering the encapsulant material 120 in at least a portion of the via 124. The conductive material 131 can then fill the entire via 124 over the seed layer, or the conductive material 131 can be applied in a “barrel” layer over the seed layer. The package 100 can optionally include a dielectric layer (not shown) over at least a portion of the encapsulant material 120, e.g., to supplement the electrical insulation function otherwise provided by the encapsulant material 120.

The conductive path 130 can be configured to electrically couple the first bond site 118 on the first side 114 of the die 110 to a second bond site 134a (e.g., a bond pad or other suitable terminal) on the back surface 126 of the encapsulant body 122. The second bond site 134a can be coupled to a solder ball 135, or other conductive bond feature that is positioned to be electrically coupled to external elements such as a printed circuit board. As illustrated in FIG. 1, the conductive path 130 can include a first conductive redistribution layer 136 electrically coupling the first bond site 118 to the through-encapsulant interconnect 132. The conductive path 130 can also include a second conductive redistribution layer 137 electrically coupling the second bond site 134a to the through-encapsulant interconnect 132. The first and second conductive redistribution layers 136 and 137 can be metallization layers (e.g., copper or aluminum), and the first conductive redistribution layer 136 can be applied over a dielectric layer (e.g., Benzocyclobutene (BCB) or polyimide (PI) at the first side 114 of the die 110.

Multiple second bond sites 134a (two of which are visible in FIG. 1) can be positioned at multiple locations along the back surface 126 of the encapsulant body 122, with the number and location of the several bond sites 134a depending on a size of the die 110 (e.g., the die width W₁) and/or the intended use of the semiconductor package 100. In a specific example, the die 110 can have a die width W₁ of approximately 2.1 mm and a length (transverse to the plane of FIG. 1) of approximately 2.1 mm. In some embodiments, the array of second bond sites 134a on the back surface 126 requires more surface area than is presented by the second side 116 of the die 110. In these embodiments, the second bond sites 134a can be in a “fan-out” arrangement, as shown in FIG. 1, with the second bond sites 134a located laterally outside the die width W₁. In another embodiment, second bond sites 134b (identified by dotted lines in FIG. 1) can be in a “fan-in” arrangement which places the second bond sites 134b, and the corresponding solder balls 135, within the boundaries of the die width W₁. Accordingly, the second bond site position can be set at any of a variety of locations along the back surface 126 of the encapsulant body 122, depending on the intended use of the packaged die 110 and the number of desired second bond sites 134a, 134b.

The encapsulant body 122 which encases the die 110, can also electrically isolate the die 110 from the conductive path 130. For example, at least the internal portion 127 of the encapsulant body 122 can provide electrical isolation between the conductive path 130 and the die walls 117. Other portions of the encapsulant body 122 can provide electrical isolation between the conductive path 130 and the second side 116 of the die 110. Accordingly, while the die 110 may include dielectric layers at the first conductive redistribution layer 136, the encapsulant body 122 can eliminate the need for such layers at the die walls 117 and, in at least some embodiments, at the second side 116 as well.

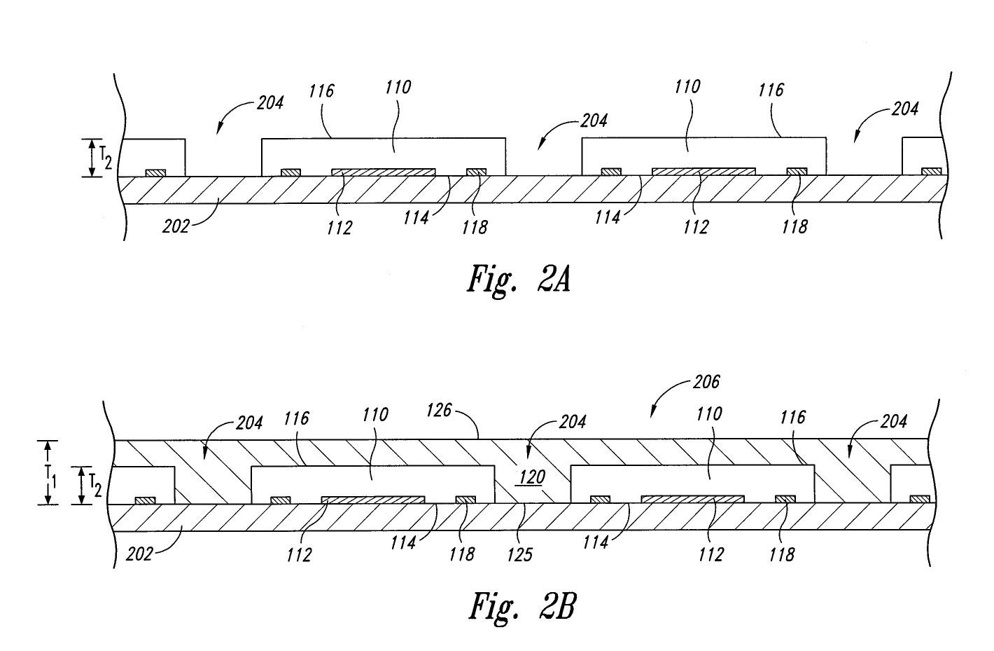

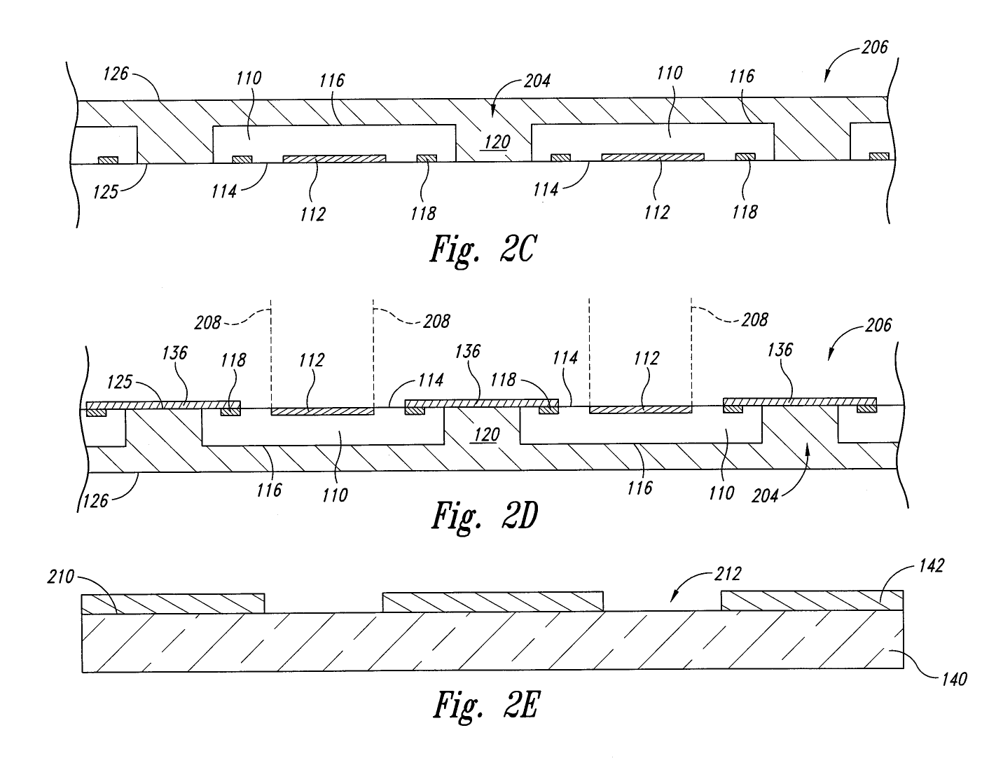

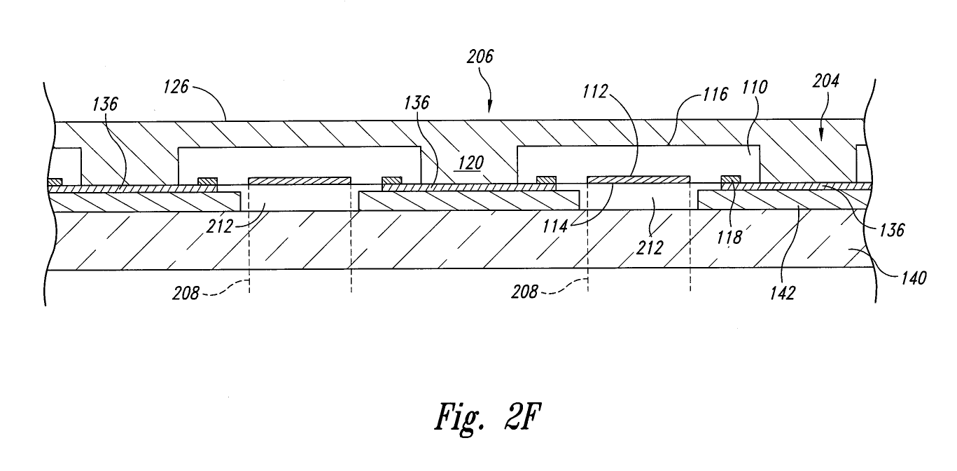

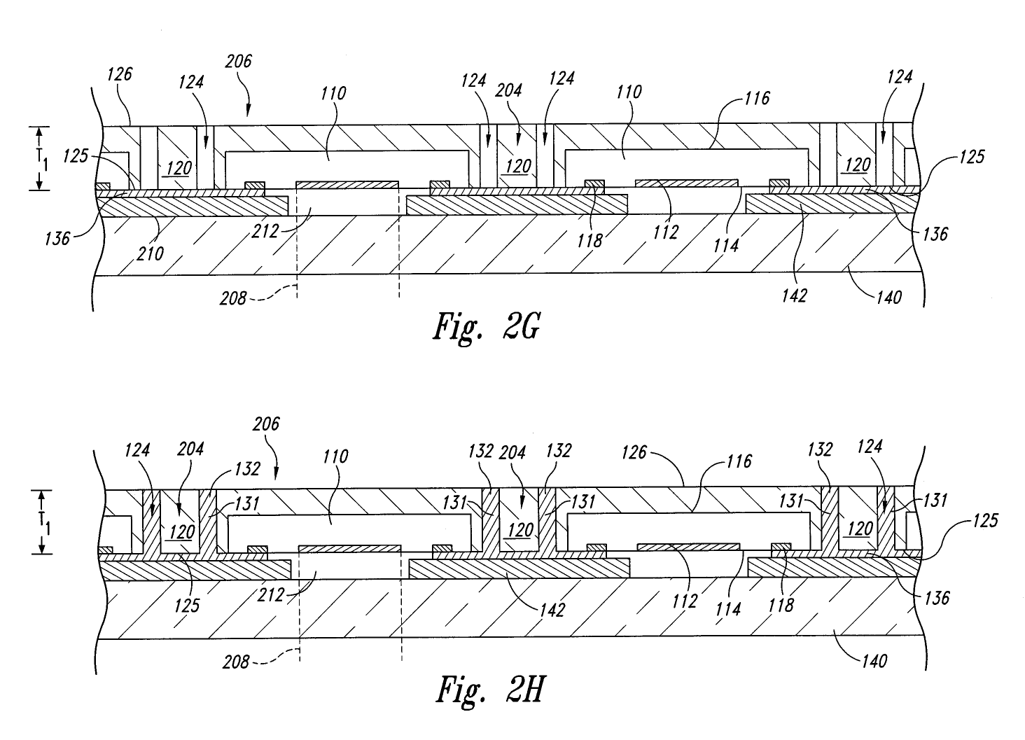

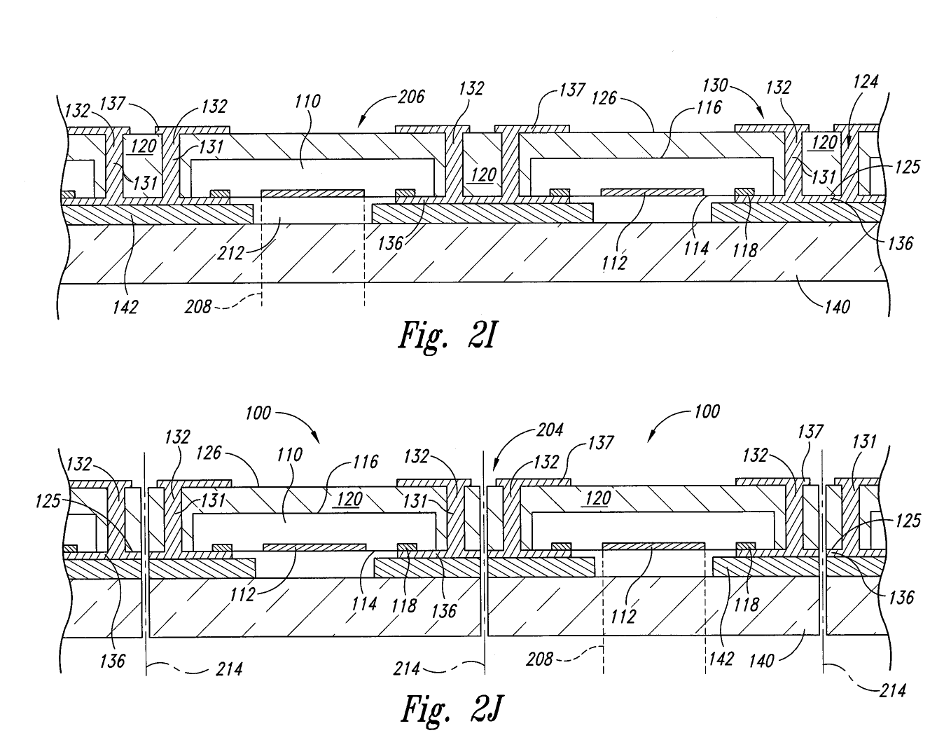

In existing devices, the conductive path includes conductive traces and/or through-die interconnects that require deposition of costly dielectric material along the through-die interconnects and at the first and second sides of the die, which can significantly increase the cost of manufacturing packaged semiconductor devices, such as imager dies. Accordingly, use of the encapsulant material 131, rather than dielectric materials, to insulate at least a portion of the die 110 from the electrical path 130 can significantly reduce the cost of manufacturing semiconductor packages 100. In addition to manufacturing costs, additional challenges are posed by current semiconductor packaging trends. As discussed above, a general trend in semiconductor manufacturing has been to decrease the size of the dies, which, in turn, increases the difficulty of electrically coupling the dies to external components through secondary bond sites on the die. For example, while wire bonding tools are capable of accommodating finer pitches between bond sites, the high density boards required to handle this pitch significantly increase the cost of commodity products. As described further below with reference to FIGS. 2A-2J, certain embodiments of the semiconductor packages 100 and methods for forming packaged semiconductor devices disclosed herein, can overcome many of these challenges by using inexpensive materials and processes, and/or providing a variety of connectivity options, which can in turn result in versatile low cost packages.

FIGS. 2A-2J illustrate stages of a method for manufacturing semiconductor packages 100 in accordance with a particular embodiment. FIG. 2A illustrates a stage of the method at which the first sides 114 of a plurality of singulated dies 110 are temporarily attached to a carrier substrate 202 (e.g., a film frame or dicing tape). The dies 110 can be temporarily attached to the carrier substrate 202 and separated from each other by gaps 204 using a pick and place process. In some embodiments, the dies 110 can be thinned or partially thinned at the wafer level to reduce an initial die thickness to a desired die thickness T₂ prior to singulating the die 110. As previously described, the die thickness T₂ can be thinned to approximately 50 to 850 microns which can be achieved through a suitable back grinding process, e.g., using chemical-mechanical processing (CMP). In other embodiments, dies that are full-thick (e.g., 500 to 850 microns) can be singulated and placed on the carrier substrate 202. Additionally, the dies 110 can be individually tested before attaching them to the carrier substrate 202. From the test, a plurality of known good dies 110 can be determined and selectively used in the method shown in FIGS. 2A-2J.

The plurality of dies 110 can be releaseably attached to the carrier substrate 202 using an adhesive layer (not shown) such an adhesive film, epoxy, tape, paste, or other suitable material that temporarily secures the dies 110 in place during packaging. In the particular embodiment shown, the first bond sites 118 are in contact with the adhesive and/or the carrier substrate 202; however, in other arrangements, the individual dies 110 may include a redistribution structure between the first bond sites 118 and the carrier substrate 202. In either arrangement, the features at the first sides 114 are temporarily covered by the carrier substrate 202, while the second sides 116 are exposed.

FIG. 2B illustrates a stage after the encapsulant material 120 has been disposed over and between the attached dies 110, filling the intermediate gaps 204, and surrounding the second sides 116. The encapsulant material 120 can be deposited in the gaps 204 using a needle-like dispenser, stenciling, molding, a glob-type dispensing process, or another suitable technique. At this stage, the encapsulant material 120 is in direct contact with the die 110 and at least partially encapsulates the dies 110 to form a multi-die encapsulant volume 206 that can subsequently be divided into individual encapsulant bodies 122 (FIG. 1) around individual dies 110.

The encapsulant material 120 can be a polymer or other suitable material that protects, strengthens, and electrically insulates the dies 110. For example, the encapsulant material 120 can be a composite mold compound, e.g., a filled mold compound that includes a filler (e.g., silica, alumina, talc), adhesives, and/or other materials that provide chemical, heat, and/or flame resistance. Accordingly, it is not necessary for the semiconductor package 100 to include a heat-resistant passivation layer (e.g., along the package exterior side walls and/or front and back surfaces 125 and 126) as is commonly used in conventional packaged devices. Suitable encapsulant materials are available from a variety of companies, including Nitto Denko Corp. of Japan, Sumitomo Bakelite Co. of Japan, ShinEtsu Chemical Co. of Japan, Kyocera Chemical Corp. of Japan, and Henkel Corp. of Gulph Mills, Pa.

The back surface 126 of the encapsulant volume 206 is generally offset from the second sides 116 such that the body thickness T₁ is greater than the die thickness T₂. In other embodiments, the back surface 126 of the encapsulant volume 206 can be generally co-planar with the second sides 116. In embodiments for which the body thickness T₁ is generally the same as the die thickness T₂, the encapsulant material 120 can be deposited such that the material does not project beyond the second sides 116. However, in other embodiments, the encapsulant material 120 can project beyond the second sides 116 and the projecting encapsulant material 120 can then be removed through a suitable back grinding process. When using a back grinding process, it is possible to remove additional material from the second sides 116 of the dies 110 in order to further reduce the die thickness T₂ and, therefore, an overall package thickness T₃ (shown in FIG. 1).

FIG. 2C illustrates a subsequent stage of the method after which the carrier substrate 202 has been removed from the encapsulant volume 206 to expose the first side 114 of the dies 110 and the front surface 125 of the encapsulant volume 206. Referring next to FIG. 2D, the first conductive redistribution layer 136 can be formed on the first sides 114 using conventional masking and deposition techniques.

FIG. 2E is a partially schematic, cross-sectional view of the cover 140 that will be placed over at least the sensors/transmitters 112 of the dies 110 shown in FIG. 2D. Referring to FIGS. 2D and 2E together, the cover 140 can be manufactured from a material that is transparent, or at least partially transparent to radiation at a target wavelength that is received or transmitted by the sensor/transmitter 112 along a radiation path 208. For example, in a particular embodiment in which the sensor/transmitter 112 includes an imager configured to receive and process radiation in the visible spectrum, the cover 140 can be made from glass. In other embodiments, the cover 140 can have other compositions, depending upon factors that include, but are not limited to, the particular characteristics of the sensor/transmitter 112. In any of these embodiments, the cover 140 can be generally rigid and self-supporting. The cover 140, as illustrated in FIG. 2E, can be sized to overlay at least the encapsulant volume 206. In other arrangements, however, the cover 140 can have other sizes or configurations to cover at least a portion of the first sides 114 to protect the sensor/transmitter 112 and/or other die-associated micro features.

As illustrated in FIG. 2E, the cover 140 includes the adhesive 142 applied to an outer surface 210. Again referring to FIGS. 2D and 2E together, the adhesive 142 is applied in a pre-selected pattern, such as through a stencil and/or printing technique, for attaching the cover 140 to the encapsulant volume 206. The adhesive 142 can include any of a variety of suitable materials, for example, a UV-curable epoxy material. The adhesive 142 can have a viscosity high enough to allow it to adhere to the outer surface 210 of the cover 140 if the cover 140 is inverted. In the embodiment shown, the adhesive 142 is not required to be optically transparent because the pattern includes adhesive windows 212, or voids, that align with the sensor/transmitter 112 in the radiation path 208. In other embodiments, the adhesive 142 can be transparent at the wavelength associated with the sensor/transmitter 112, e.g., the adhesive 142 can be an optical-grade adhesive. In such an instance, the adhesive 142 can optionally be disposed over the entire outer surface 210 of the cover 140, including the windows 212, as it will not interfere with the operation of the sensor/transmitter 112.

Referring next to FIG. 2F, the cover 140 is positioned transverse to the radiation paths 208 and attached to the encapsulated dies 110. The windows 212 are aligned with the corresponding radiation paths 208, and (in this embodiment) the adhesive 142 does not extend inwardly into the radiation path 208. Optionally, the encapsulant volume 206 and cover 140 may be placed under pressure to enhance the seal between the cover 140 and the encapsulant volume 206. The adhesive 142 can optionally be cured e.g., by exposure to UV radiation.

FIG. 2G illustrates a stage of the method after a plurality of vias 124 (e.g., encapsulant voids) are formed in the encapsulant volume 206 between the neighboring dies 110. In this particular arrangement, the vias 124 are formed through the encapsulant volume 206 from the back surface 126 and terminate at the first conductive redistribution layer 136. The vias 124 can be laser drilled, mechanically drilled, or etched. If a laser drilling process is used, the front surface 125 of the encapsulant volume 206 can be detected by sensing reflected light when the laser beam reaches the first conductive redistribution layer 136. At this point, the laser drilling process can be halted, with the via 124 having a length generally equal to the body thickness T₁. The via 124 can have any of a variety of cross-sectional shapes (e.g., circular) and/or widths (e.g., 100 microns), suitable for forming the conductive path 130 (shown in FIG. 1).

FIG. 2H illustrates a subsequent stage of the method in which the vias 124 have been filled with the conductive material 131 and configured to conduct signals from the front surface 125 to the back surface 126 of the encapsulant volume 206. At this stage, the vias 124 can include a seed layer (not shown) deposited directly on at least a portion of the encapsulant material 120 in the vias 124 (e.g., via side walls between the back surface 126 and the front surface 125). The seed layer can be composed of copper or other suitable materials. Suitable seed layer plating materials are available from a variety of companies, including Atotech of Berlin, Germany; Uyemura of Hirakata, Japan; Technic of Cranston, R.I.; and Rohm and Hass of Philadelphia, Pa. Seed layer materials can be deposited using non-selective, conventional deposition techniques, such as chemical vapor deposition (CVD), physical vapor deposition (PVD), atomic layer deposition, and/or plating techniques.

Following seed layer deposition, the vias 124 are filled or partially filled with conductive material 131, such as a conductive metal or combination of conductive metals (e.g., copper, gold, and/or nickel). The conductive material 131 in the vias 124 form through-encapsulant interconnects 132 electrically coupled to the first conductive redistribution layer 136 at the front surface 125.

In a subsequent stage of the method, illustrated in FIG. 2I, a second conductive redistribution layer 137 can be disposed on at least a portion of the back surface 126 of the encapsulant volume 206. The second conductive redistribution layer 137 is electrically coupled to the through-encapsulant interconnects 132 and provides electrical contact points for second bond sites 134a, 134b (shown in FIG. 1). In a particular embodiment, the second redistribution layer 137 can be disposed directly on the back surface 126 without a separate dielectric layer, as discussed above, with the encapsulant material 120 electrically isolating the second side 116 of the die 110 from the second redistribution layer 137. In other embodiments, a dielectric layer can be disposed prior to forming the second conductive redistribution layer 137, though as discussed further below, it may be more cost effective to eliminate this dielectric layer.

FIG. 2J illustrates a stage of the method after neighboring semiconductor packages 100 have been singulated and separated from each other. The semiconductor packages 100 can be separated by cutting through the cover 140 and the encapsulant material 120 in the gaps 204, e.g., with a dicing blade or water jet. In the illustrated embodiment, the semiconductor packages 100 are cut along dicing streets 214 located between neighboring through-encapsulant interconnects 132; however, in other arrangements, the packages 100 can be cut along dicing streets 214 located with respect to other adjacent features.

In a particular embodiment, the semiconductor packages 100 can be manufactured using only good known dies. Conventional wafer-level packaging techniques exact a penalty for packaging and processing all dies, both good and bad, at a stage in the manufacturing process when yields can be low. Accordingly, costly packaging, processing materials and time can be saved when using the method illustrated in FIGS. 2A-2J to package only known good dies. Additionally, by using mold compound to encapsulate the dies, and by routing the conductive path through the encapsulant body, rather than through the die substrate as in conventional packages, embodiments of the foregoing method do not require costly dielectric and passivation layers to electrically insulate the die from the conductive path. Furthermore, embodiments of the method illustrated in FIGS. 2A-2J can be performed using wafer-level processing techniques, further reducing manufacturing costs.

Conventional semiconductor packages typically include a plurality of separately manufactured package subunits (e.g., ceramic packages with pre-formed cavities), which are designed to provide support and protection for the die once assembled. In these conventional packages, manufacturers have decreased both the thicknesses of the dies and the size of the package subunits to accommodate an overall package thickness suitable for variety of applications. However, the existing techniques available to manufacture and assemble these package subunits limit the degree to which they can be made smaller. Therefore, significant decreases in package thicknesses can be achieved by dramatically thinning the dies (e.g., to approximately 100 microns). In contrast, an additional feature of at least some embodiments of the semiconductor packages 100 is that the dies 110 need not be thinned or need not be thinned as much as some existing dies. For example, the semiconductor package 100 can incorporate dies having a robust thickness (e.g., full thick or nearly full-thick) while still limiting the overall package thickness T₃ (FIG. 1). Depending on the die thickness T₂ (e.g., greater than 100 microns), the body thickness T₁ of the encapsulant body 122 can be easily altered to accommodate and support the die 110 while still achieving a low overall package thickness T₃ (e.g., approximately 1.1 mm to approximately 1.4 mm).

Embodiments of the semiconductor packages 100 can also enable a wide range of suitable bond site arrays for providing electrical connection to external elements, such as printed circuit boards. For example, by providing an extended surface area for solder balls on the back surface of the package, the semiconductor packages can couple to a variety of circuit boards with a large array. Accordingly, low resolution applications can cost-effectively include solder balls placed in a fan-out arrangement for connecting to lower cost printed circuit boards, while higher end applications can include solder balls placed in a fan-in arrangement for packages having bond sites with finer pitches.

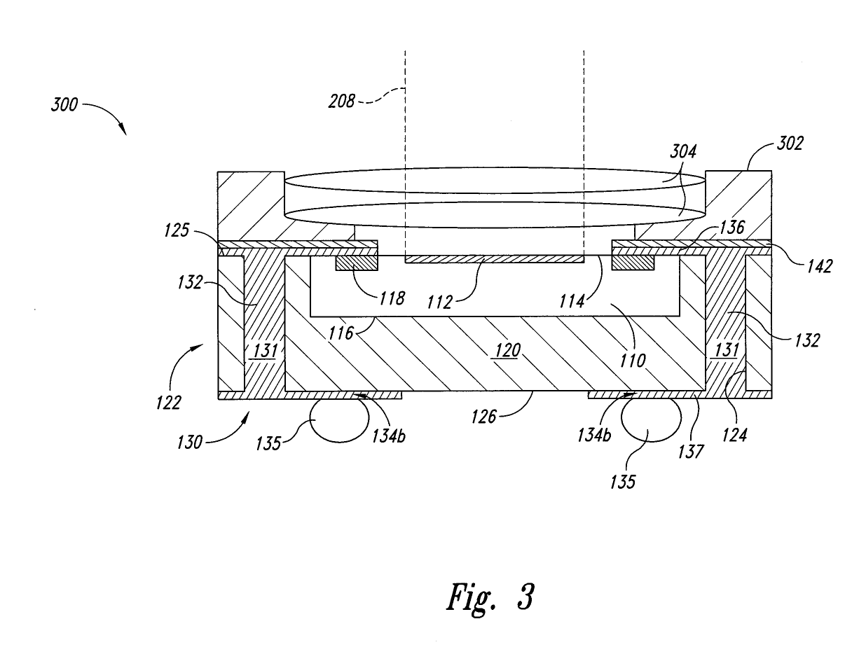

FIGS. 3-6C illustrate additional embodiments of packaged semiconductor devices and methods for manufacturing packaged semiconductor devices in accordance with the present disclosure. These packaged devices can include several features generally similar to the semiconductor package 100 described above with respect to FIG. 1 which, for purposes of brevity, are not described in detail below.

FIG. 3 is a partially schematic, cross-sectional illustration of a semiconductor package 300 that is configured in accordance with another embodiment of the disclosure. The semiconductor package 300 can be generally similar to the package 100 described above with respect to FIG. 1. The semiconductor package 300 differs from the package 100, however, in that the package 300 includes a lens module 302 (in lieu of the cover 140) positioned in the radiation path 208 along which the sensor/transmitter 112 receives and/or transmits radiation signals. The lens module 302 is positioned adjacent to the die 110 and the encapsulant body 122 and, using the adhesive 142 configured as previously described, the lens module 302 can be secured in a position along the radiation path 208. The lens module 302 can include one or more lenses 304 that can be transparent to or at least partially transparent to radiation at the target wavelength. Semiconductor packages 300 having the lens module 302 can be used in cameras, camera phones, and other electronic applications requiring specific lens features.

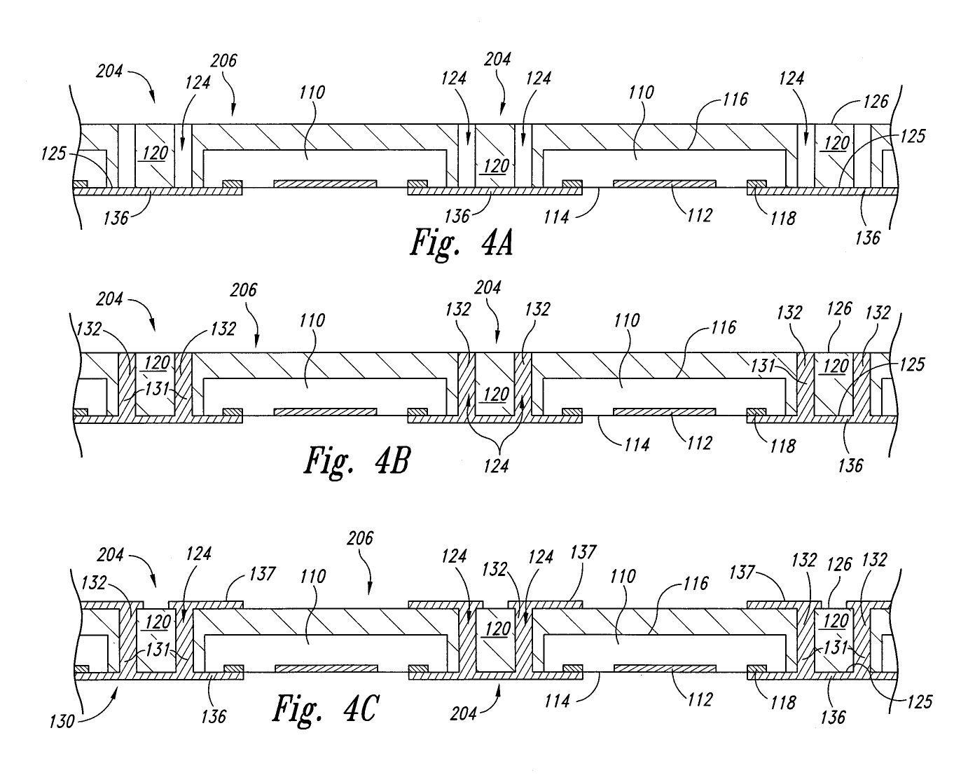

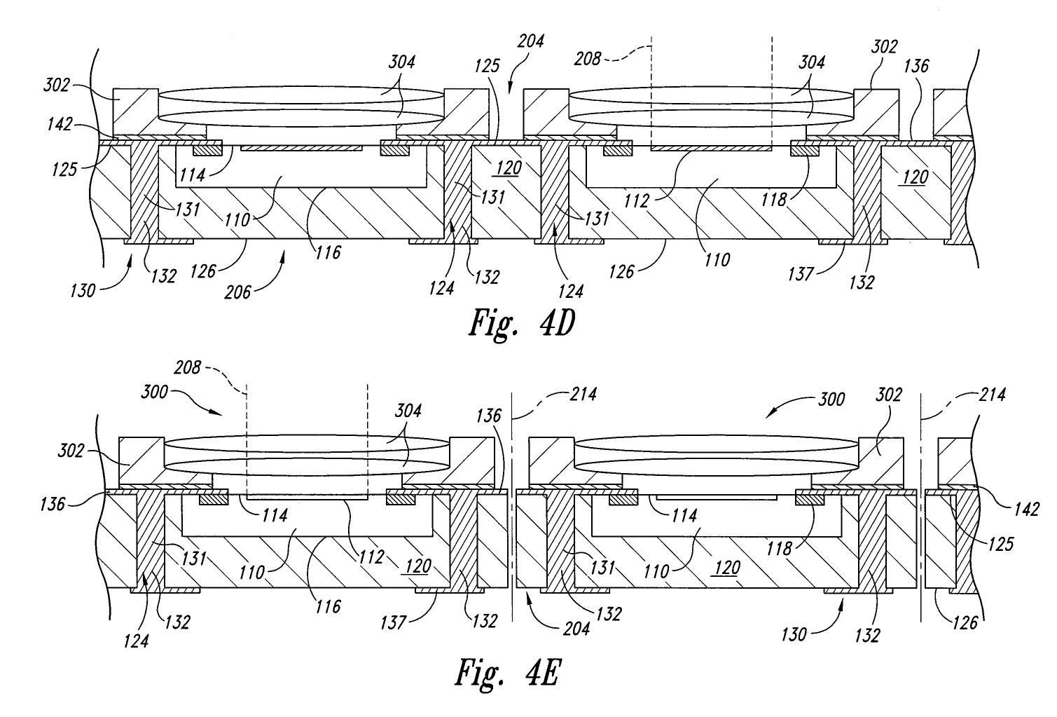

FIGS. 4A-4E illustrate stages of a method for manufacturing semiconductor packages 300 in accordance with a particular embodiment. Initial stages of the method are generally similar to stages described above with reference to FIGS. 2A-2D, however, the stages following the stage illustrated in FIG. 2D are different in that the conductive path 130 is fully formed prior to securing a cover and/or a lens module 302 to the die 110. FIG. 4A illustrates a subsequent stage in the method after the first conductive redistribution layer 136 is disposed on the front surface 125 and is electrically connected to first bond sites 118 at the first sides 114 (e.g., active sides). In this stage, the plurality of vias 124 are formed by removing encapsulant material 120 between the back surface 126 and the front surface 125 of the encapsulant volume 206 in the gaps 204 between the individual dies 110. Specifically, the vias 124 can be laser drilled, mechanically drilled, or etched from the back surface 126 and terminate at the first conductive redistribution layer 136 on the front surface 125.

In the next stage, illustrated in FIG. 4B, the vias 124 can be filled with conductive material 131 to form through-encapsulant interconnects 132 that are electrically coupled to the first conductive redistribution layer 136. The through-encapsulant interconnects 132 are formed in a manner generally similar to that described above with respect to FIG. 2H. For example, a seed layer (not shown) can be applied to the encapsulant material 120 in at least a portion of the via 124 prior to filling the vias 124 with the conductive material 131.

FIG. 4C illustrates the dies 110 after the second conductive redistribution layer 137 is formed along at least a portion of the back surface 126 of the encapsulant volume 206. The second conductive redistribution layer 137 is electrically coupled to the through-encapsulant interconnects 132 to complete the conductive path 130 from the first bond sites 118 to the back surface 126 of the encapsulant volume 206.

FIG. 4D illustrates a subsequent stage of the method after a plurality of lens modules 302 are mounted to the encapsulant volume 206 with the lenses 304 positioned in the radiation path 208. The lens modules 302 can be mounted with an adhesive 142 similar to the adhesive described above with respect to mounting the cover 140 of FIG. 1. In one embodiment, the adhesive 142 can form an adhesive layer between the lens module 302 and the front surface 125 of the encapsulant volume 206 and/or the first side 116 of the dies 110.

FIG. 4E illustrates a further stage in the method after the individual semiconductor packages 300 are singulated. The individual packages 300 can be cut along dicing streets 214 in the gaps 204 between neighboring through-encapsulant interconnects 132, as shown, or between other packaged features (e.g., the dies 110) in other arrangements. While having many of the same features and characteristics as semiconductor packages 100 (FIG. 1), the semiconductor packages 300, having the lens module 302 instead of simple covers, can be used in a variety of semiconductor applications requiring one or more lenses 304 positioned in the radiation path 208, such as digital cameras, camera phones, and other focusing and zoom-enabling applications.

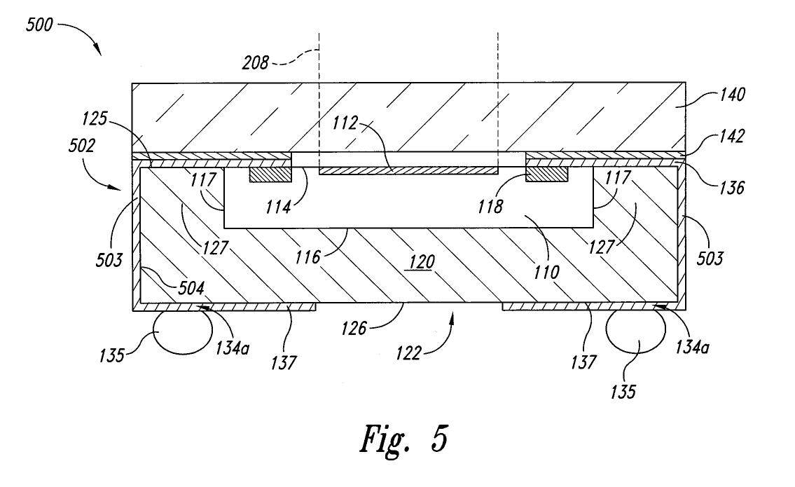

FIG. 5 is a partially schematic, cross-sectional illustration of a semiconductor package 500 configured in accordance with another embodiment of the disclosure. Several features of the semiconductor package 500 can be generally similar to those of the package 100 described above with respect to FIG. 1. For example, the semiconductor package 500 can include a die 110 having a sensor/transmitter 112 at a first side 114 (e.g., an active side). The sensor/transmitter 112 can receive and/or transmit radiation signals at a target wavelength along the radiation path 208. Additionally the semiconductor package 500 can include a cover 140 positioned in the radiation path 208. The semiconductor package 500 also includes the encapsulant material 120 configured to at least partially encase the die 110. As previously described with respect to FIGS. 1 and 3, the encapsulant material 120 can be molded to form the encapsulant body 122 (e.g., a molded support structure) in direct contact with the die 110.

The semiconductor package 500 differs from the package 100 shown in FIG. 1 in that the final semiconductor package 500 does not have through-encapsulant interconnects. Instead, the semiconductor package 500 includes a conductive path 502 that has a conductive layer 503 disposed along encapsulant body side walls 504 between the front surface 125 and the back surface 126. The conductive layer 503 can include conductive metals, such as nickel, copper, gold, and/or aluminum, and can be applied using known techniques for applying redistribution layers.

Functionally, the conductive path 502 transmits signals from the first bond sites 118 to the second bond sites 134a at the back surface 126 of the encapsulant body 122. The conductive path 502 includes the conductive layer 503 applied to the encapsulant body 122 along at least portions of each of the front surface 125, the side walls 504, and the back surface 126. Similar to the embodiments described above with reference to FIGS. 1 and 3, the conductive path 502 is separated from the die 110 by a portion 127 of the encapsulant body 122, thereby providing electrical isolation between the conductive path 502 and the die 110. Accordingly, no separate dielectric layer is positioned along the die walls 117 and, in some arrangements, the second side 116. Furthermore, in particular embodiments, no passivation layer is formed at the encapsulant body side walls 504 and, in some arrangements, the back surface 126. An additional feature of the semiconductor package 500 illustrated in FIG. 5 is that the conductive layer 503 at the side walls 504 of the encapsulant body 122 can provide additional areas for electrical contacts between the package 500 and external elements. For example, two semiconductor packages 500 can be electrically coupled to each other by connecting the conductive layers 503 of each at the side walls 504.

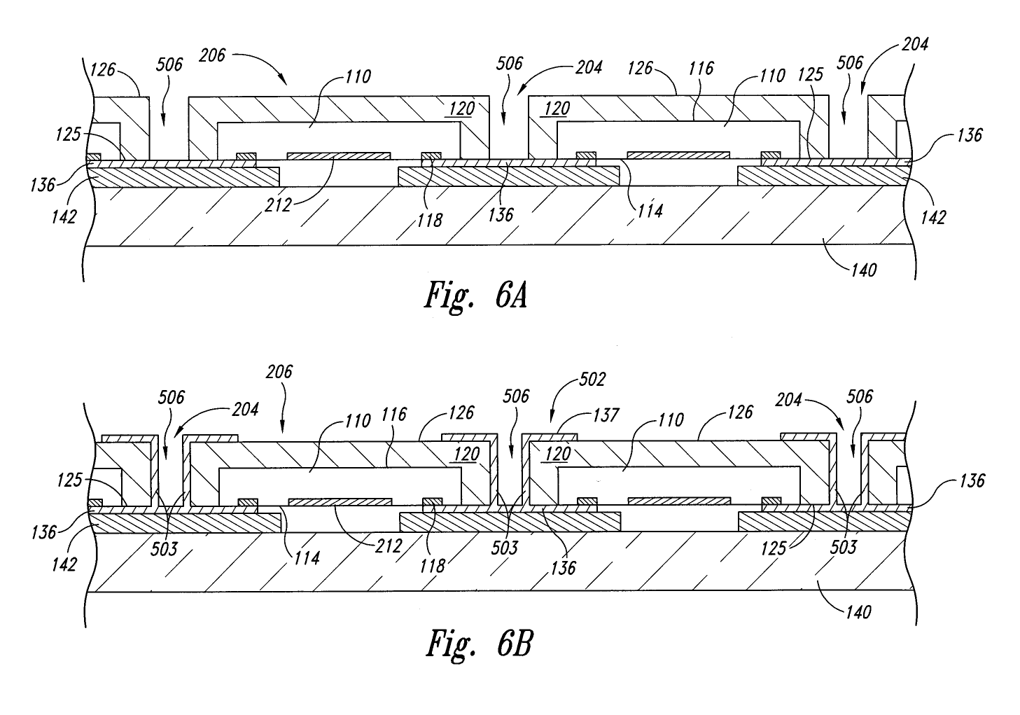

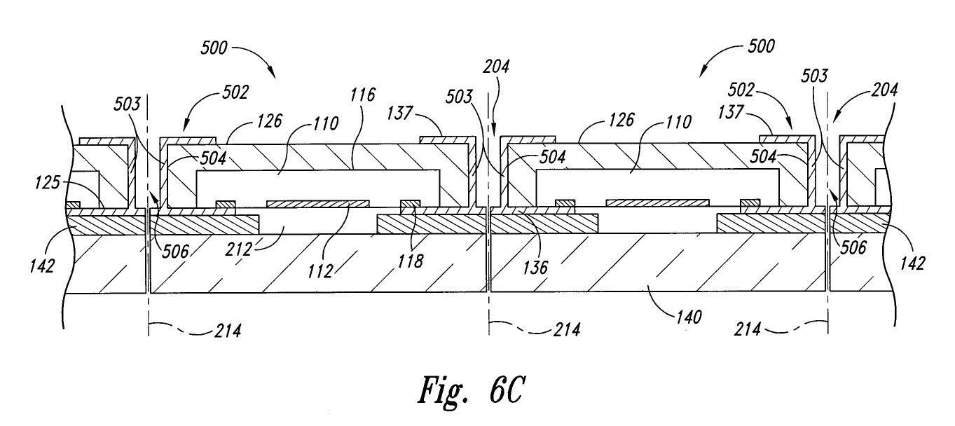

FIGS. 6A-6C illustrate stages of a method for manufacturing the semiconductor packages 500 in accordance with a particular embodiment. Initial stages of manufacturing semiconductor packages 500 are generally similar to stages described above with reference to FIGS. 2A-2F. The method differs following the stage illustrated in FIG. 2F. Accordingly, FIG. 6A illustrates a subsequent stage in the method after a plurality of central vias 506 have been formed through the encapsulant material 120 in the gaps 204 between adjacent dies 110. The central vias 506 extend through the encapsulant volume 206 from the back surface 126 and terminate at the first conductive redistribution layer 136 at the front surface 125. The central vias 506 can have any of a variety of suitable shapes and/or widths. For example, the central vias 506 can be formed such that the central vias have via side walls oriented at a 90° angle with respect to the front and back surfaces 125 and 126. Additionally, the central vias 506 can be formed by removing encapsulant material 120 in the gaps 204 by sawing, laser drilling, etc.

FIG. 6B illustrates a subsequent stage of the method after the conductive layer 503 has been disposed in the central via 506 to at least coat a portion of the encapsulant material 120 in the central via 506 (e.g., the inwardly facing via side walls). For example, the conductive layer 503 can be plated to “barrel-coat” the encapsulant material 120 exposed through the encapsulant volume 206 in the gaps 204. In other arrangements, the conductive layer 503 can be applied to selected exposed portions of the encapsulant material 120 by using conventional masking techniques with or without an initial seed layer (not shown). The conductive layer 503 can be electrically coupled with the first conductive redistribution layer 136 on the front surface 125. Additionally the conductive layer 503 can continue along the back surface 126 of the encapsulant volume 206 to form the second conductive redistribution layer 137.

In the next stage, illustrated in FIG. 6C, individual semiconductor packages 500 can be separated from each other by cutting through the first conductive redistribution layer 136 and/or the cover 140 along dicing streets 214 through the central vias 506. As illustrated, the individual semiconductor packages 500 have the conductive layers 503 remaining on the encapsulant body side walls 504.

While FIGS. 6A-6C illustrate a particular method for manufacturing semiconductor packages 500, other methods may be used to package these devices and form a conductive path 502 around a perimeter of the packaged device. For example, the conductive layers 503 may be applied after the separation process, e.g., after the semiconductor packages 500 have been singulated. Specifically, the encapsulated dies 110 may be separated from each other by cutting through the external vias 506, and after singulation, the conductive layer 503 (and/or seed layer) may be applied by conventional vapor deposition techniques, plating, etc., to at least selected portions of each of the side walls 504 and the back surfaces 126.

FIG. 7 is a flow chart illustrating an embodiment of a method 700 for manufacturing packaged semiconductor assemblies. The method 700 can include encapsulating a portion of the semiconductor die having a sensor/transmitter positioned in a radiation path (block 710). The encapsulant can form an encapsulant body having oppositely facing front and back surfaces and exposed outer edges between the surfaces. The method 700 can further include removing a portion of the encapsulant body to form a via between the front surface and back surface (block 720). Additionally, the method 700 can include forming a conductive path from a first bond site on an active side of the die to the back surface that includes conductive material disposed in the via (block 730). The back surface can additionally include a second bond site along the conductive path configured to electrically couple external elements. Following step 730, the method 700 can further include positioning a cover transverse to the radiation path (block 740).

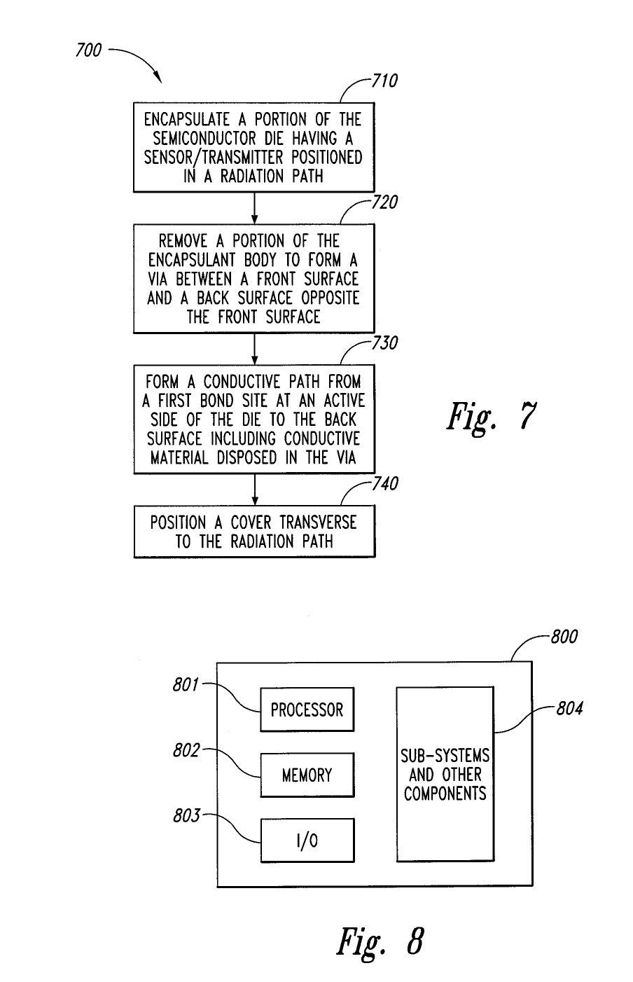

FIG. 8 illustrates a system 800 that includes a semiconductor package configured and/or manufactured in accordance with the embodiments described above with reference to FIGS. 1-7. More specifically, a packaged semiconductor device as described above with reference to FIGS. 1-7 can be incorporated into any of a myriad of larger and/or more complex systems, and the system 800 is merely a representative sample of such a system. The system 800 includes a processor 801, a memory 802 (e.g., SRAM, DRAM, flash, or other memory devices), input/output devices 803 (e.g., a sensor and/or a transmitter), and/or subsystems and other components 804. Semiconductor packages having any one or a combination of the features described above with reference to FIGS. 1-7 may be included in any of the devices shown in FIG. 8. The resulting system 800 can perform any of a wide variety of computing processing, storage, sensing, imaging, and/or other functions. Accordingly, the system 800 can include, without limitation, a computer and/or other data processor, for example, a desktop computer, laptop computer, Internet appliance, handheld device, multi-processor system, processor-based or programmable consumer electronics, network computer, and/or mini-computer. Suitable hand-held devices for these systems can include palm-type computers, wearable computers, cellular or mobile phones, personal digital assistants, music players, etc. The system 800 can further include a camera, light or other radiation sensor, server and associated server subsystems, and/or any display device. In such systems, individual dies can include imager arrays, such as CMOS imagers. Components of the systems 800 may be housed in a single unit or distributed over multiple, interconnected units (e.g., through a communications network). The components of the system 800 can accordingly include local and/or remote memory storage devices and any of a wide variety of computer-readable media.

From the foregoing, it will be appreciated that specific embodiments have been described herein for purposes of illustration, but that various modifications may be made in other embodiments. For example, while certain of the embodiments described above were described in the context of semiconductor packages that include a sensor/transmitter, many of the foregoing features may be included in semiconductor packages that do not include a sensor/transmitter. Specific elements of any of the foregoing embodiments can be combined or substituted for elements in other embodiments. Further, while features and characteristics associated with certain embodiments have been described in the context of those embodiments, other embodiments may also exhibit such features and characteristics, and not all embodiments need necessarily exhibit such features and characteristics. Accordingly, the embodiments of the disclosure are not limited except as by the appended claims.

I/We claim:

1. A semiconductor system, comprising:
a semiconductor package that includes:
a die with a first side, a second side facing opposite from the first side, a first bond site toward the first side, and a sensor/transmitter coupled to the first bond site and positioned to receive/transmit a target radiation wavelength along a radiation path;
a cover generally transparent to the target wavelength and positioned transverse to the radiation path;
an encapsulant at least partially encapsulating the die, the encapsulant having a front surface generally flush with the first side and a back surface facing opposite from the front surface;
a second bond site positioned toward the back surface;
a via extending through the encapsulant; and
a conductive path coupled between first and second bond sites and including a conductive material disposed in the via.

2. The system of claim 1 wherein the back surface is offset from the second side of the die.

3. The system of claim 1 wherein the back surface is generally flush with the second side of the die.

4. The system of claim 1 wherein the conductive path includes a conductive redistribution layer electrically coupling the first bond site to the conductive material disposed in the via.

5. The system of claim 1 wherein the conductive path includes a conductive redistribution layer electrically coupling the second bond site to the conductive material disposed in the via.

6. The system of claim 5 wherein the encapsulant is the only dielectric material between the die and the conductive redistribution layer.

7. The system of claim 1 wherein the second bond site is located laterally outside a width of the die.

8. The system of claim 1 wherein the encapsulant is the only dielectric material between the die and the conductive material in the via.

9. The system of claim 1 wherein the package further includes—
a plurality of dies spaced apart from one another by gaps, the individual dies having a first bond site electrically coupled to a sensor/transmitter;
encapsulant in the gaps and at least partially encapsulating the dies to form a molded encapsulant volume; and
a plurality of vias extending through the molded encapsulant volume in the gaps, and wherein the conductive material is in the vias.

10. The system of claim 9, further comprising a conductive redistribution structure electrically coupling the individual first bond sites and the conductive material disposed in the individual vias.

11. The system of claim 9 wherein the individual vias include an encapsulant void having side walls, and wherein at least a portion of the side walls include a conductive coating electrically coupled to the individual first bond sites.

12. The system of claim 9 wherein the cover is sized to overlay at least the molded encapsulant volume.

13. A system of claim 1, further including a memory and a processor, and wherein the semiconductor package is operatively coupled to at least one of the memory and the processor.

14. A semiconductor system, comprising:
a semiconductor package that includes:
a die having a first side, a second side facing opposite from the first side, die walls extending between the first side and second side, and a first bond site at the first side, and wherein the die includes at least one of a sensor positioned to receive radiation along a radiation path at a target wavelength, and a transmitter configured to transmit radiation along the radiation path at the target wavelength;
a molded support structure formed of encapsulant in direct contact with the die, the molded support structure having a front surface generally flush with the first side, a back surface opposite the front surface, and a plurality of exterior side walls extending between the front surface and the back surface;
a conductive material applied to at least a portion of the molded support structure at the front surface, the back surface, and exterior side walls to form a conductive path from the first bond site to a second bond site at least proximate to the back surface; and
a cover at least generally transparent to the target wavelength and positioned transverse to the radiation path.

15. The system of claim 14 wherein a thickness of the die is less than a thickness of the molded support structure.

16. The system of claim 14 wherein a thickness of the die is generally the same as a thickness of the molded support structure, and wherein the second bond site is positioned at one of the back surface and the second side.

17. The system of claim 14 wherein the encapsulant is the only dielectric material between the conductive material at the exterior side walls and the die.

18. The system of claim 14 wherein a portion of the molded support structure is between the die and the conductive path along the die walls, and wherein the package includes no passivation layer adjacent to the encapsulant at the exterior side walls.

19. The system of claim 14 wherein a portion of the molded support structure is between the die and the conductive path along the die walls and the second side, and wherein the package includes no passivation layer adjacent to the encapsulant at the exterior side walls and the back surface.

20. The system of claim 14 wherein the second bond site is at the back surface located inwardly from the conductive material at the exterior side walls and laterally outside a width of the die.

21. The system of claim 14, further including a memory and a processor, and wherein the semiconductor package is operatively coupled to at least one of the memory and the processor.

22. A method for packaging a semiconductor die, comprising:
encapsulating a portion of the semiconductor die with encapsulant material to form an encapsulant body, the encapsulant body having a front surface, a back surface opposite the front surface, and an exposed outer edge between the front surface and the back surface, wherein the semiconductor die includes a sensor/transmitter configured to receive/transmit radiation at a target wavelength along a radiation path, the sensor/transmitter electrically coupled to a first bond site at an active side of the die;
positioning a cover transverse to the radiation path, wherein the cover is generally transparent to the target wavelength;
removing a portion of the encapsulant body between the back surface and the front surface to form a via through the encapsulant material; and
forming a conductive path from the first bond site at the active side to the back surface of the encapsulant body, the conductive path including conductive material disposed in the via.

23. The method of claim 22, further comprising:
supporting the active side of the semiconductor die on a carrier substrate before encapsulating a portion of the semiconductor die; and
after encapsulating a portion of the semiconductor die, removing the carrier substrate to expose the active side of the semiconductor die.

24. The method of claim 22 wherein forming the conductive path includes electrically connecting the first bond site to a second bond site, the second bond site positioned laterally outside a width of the semiconductor die for electrically coupling external elements.

25. The method of claim 22 wherein forming a conductive path includes coupling a conductive redistribution layer between the first bond site and the conductive material disposed in the via.

26. The method of claim 22 wherein:
encapsulating a portion of the semiconductor die includes applying the encapsulant material directly to the die without an intermediate dielectric material; and
forming a conductive path includes applying conductive material directly to the encapsulant body without intermediate dielectric material.

27. The method of claim 26 wherein:
encapsulating the portion of the semiconductor die includes molding the encapsulant material around a plurality of dies separated from each other by gaps;
removing a portion of the encapsulant body includes forming at least one via in individual gaps; and
the method further comprises cutting through the vias to separate neighboring packaged semiconductor dies from each other and exposing the conductive layer on at least a portion of the exposed outer edge of the encapsulant body.

28. The method of claim 22 wherein encapsulating the portion of the semiconductor die includes forming the encapsulant body around a plurality of dies separated from each other by gaps, the gaps filled with encapsulant material, and wherein the method further comprises:
forming a first conductive redistribution layer at the front surface electrically coupled to individual die first bond sites;
removing a portion of the encapsulant material in the gaps to form a plurality of vias through the encapsulant body;
filling individual vias with conductive material to form through-encapsulant interconnects terminating at the first conductive redistribution layer;
forming a second conductive redistribution layer at the back surface to electrically couple the through-encapsulant interconnects to a second bond site, the second bond site positioned to be electrically connected to external elements; and
cutting through at least the encapsulant material in the gaps to singulate a packaged semiconductor device.

29. The method of claim 22, further comprising testing the semiconductor die before encapsulating the semiconductor die, and wherein encapsulating the semiconductor die includes encapsulating only a known good die.

30. A method of manufacturing packaged semiconductor assemblies, comprising:
attaching a plurality of singulated dies to a temporary carrier, the dies being spaced apart from one another by gaps, wherein individual dies have an active side attached to the temporary carrier and a second side facing opposite the active side, and wherein the dies include a sensor/transmitter positioned along a radiation path;
placing an encapsulant material in the gaps and at least partially around the second side to form a molded volume, the molded volume having a front surface and a back surface;
positioning a cover transverse to the radiation path, the cover being generally transparent to a target wavelength receivable/transmittable by the sensor/transmitter; and
forming a plurality of conductive paths through the encapsulant material in the gaps between the front surface and the back surface.

31. The method of claim 30 wherein the conductive paths include a conductive interconnect through the molded volume between the front surface and the back surface, and wherein the individual dies have a first bond site at the active side, the first bond site being electrically coupled to the sensor/transmitter, and the method further includes electrically coupling the first bond site to the conductive interconnect to form the conductive path from the active side to the back surface.

32. The method of claim 31, further comprising positioning a second bond site at the back surface, the second bond site electrically coupled to the conductive interconnect.

33. The method of claim 30 wherein forming a plurality of conductive paths includes removing encapsulant material from at least a portion of the molded volume in the gaps to form encapsulant voids, and filling the encapsulant voids with conductive material.

34. The method of claim 30, further comprising cutting at least the encapsulant material in the gaps to singulate the packaged semiconductor assemblies.

35. The method of claim 30, further comprising removing encapsulant material from the back surface to thin the molded volume.

36. The method of claim 30 wherein forming a plurality of conductive paths includes—
removing encapsulant material from at least a portion of the molded volume in the gaps to form encapsulant voids having side walls;
disposing a conductive layer on at least a portion of the side walls; and
cutting along dicing streets and through the encapsulant voids to separate individual encapsulated dies.

37. The method of claim 30 wherein forming a plurality of conductive paths includes—
cutting through the encapsulant material in the gaps to separate individual encapsulated dies, the encapsulated dies having exposed edges between the front surface and the back surface; and
disposing a conductive layer on at least the exposed edges.
